(19) United States
(12) Patent Application Publication
(10) Pub. No.: US 2004/0029339 A1
(43) Pub. Date: Feb. 12, 2004

(54) Plasma processing apparatus and plasma processing method

(76) Inventors: Naoko Yamamoto, Osaka-shi (JP); Tatsushi Yamamoto, Ikoma-gun (JP); Masaki Hirayama, Sendai-shi (JP); Tadahiro Ohmi, Sendai-shi (JP)

Correspondence Address: Dike, Bronstein, Roberts & Cushman, Intellectual Property Practice Group, Edwards & Angell, LLP, P.O. Box 9169, Boston, MA, 02209, US

(21) Appl. No.: 10/407,549

(22) Filed: Apr. 4, 2003

(30) Foreign Application Priority Data
Apr. 9, 2002 (JP) 2002-106744

(51) Int. Cl. H01L 21/8238

(52) U.S. Cl. 438/222

(57) ABSTRACT

Provided are a plasma processing apparatus and a plasma processing method capable of improving uniformity of plasma processing without increasing a necessary output of a power supply. A plasma processing apparatus includes: a processing chamber performing processing using a plasma; and three or more electromagnetic wave introducing parts connected to the processing chamber to introduce into the processing chamber an electromagnetic wave for driving a reaction gas supplied into the processing chamber into a plasma state, wherein of combinations of every two adjacent ones of said three or more electromagnetic wave introducing means located in a region adjacent to said processing chamber, a distance between the two adjacent electromagnetic wave introducing means forming one of said combinations is different from a distance between the two adjacent electromagnetic wave introducing means forming another one of said combinations.

### BACKGROUND OF THE INVENTION

1. Field of the Invention

The present invention relates to a plasma processing apparatus and a plasma processing method, and more particularly to a plasma processing apparatus such as an etching apparatus, a film forming apparatus and an ashing apparatus and to a plasma processing method, which are used in fabrication processes for devices such as a semiconductor device, a liquid crystal display and a solar cell.

2. Description of the Background Art

Conventionally, a plasma processing apparatus, which performs film formation and etching on a substrate, has been known in a fabrication process for devices such as a semiconductor device and a liquid crystal display (LCD). Along with a trend, in recent years, toward a large-sized substrate for use in fabrication of a liquid crystal display and a semiconductor device, a plasma processing apparatus processing a substrate has been developed to a large-scale one for processing a large-sized substrate.

Especially, as for a plasma processing apparatus for use in fabrication of a liquid crystal display, development has been done of an apparatus of the kind to process a substrate having one or more meters square. In such a plasma processing apparatus, a problem has arisen of uniformity of a generated plasma and more particularly, of uniformity of plasma processing itself.

A plasma processing apparatus using an inductively coupled plasma source or a microwave plasma source features that a plasma source and a biased state of a substrate can be controlled independently of each other compared with a plasma processing apparatus using a capacitively coupled plasma source that has traditionally used as the main stream. Therefore, a plasma processing apparatus with an inductively coupled or microwave plasma source can be said to be more excellent in aspects of uniformity and controllability of a plasma and plasma processing than one with a capacitively coupled plasma source. For this reason, a plasma processing apparatus with an inductively coupled or microwave plasma source has come to be widely used in recent years.

Examples of a plasma processing apparatus with an inductively coupled or microwave plasma source as described above include a plasma processing apparatus using a microwave, an ICP plasma processing apparatus and a helicon wave plasma processing apparatus. In the cases of the plasma processing apparatuses, a frequency electromagnetic wave is used that has a frequency as high as in the range of from about 10 MHz to about 10 GHz. Energy of such an electromagnetic wave is usually introduced through a dielectric into a processing chamber for performing plasma processing. As a dielectric in use, there is used a dielectric plate or a dielectric plate part of which is processed mechanically, or the like.

In such a plasma processing apparatus, a necessity arises for using a dielectric with the largest possible size to introduce an electromagnetic wave over a wide area in order to secure uniformity of processing on a large-sized substrate of one or more meters square. On the other hand, a dielectric usually plays a role as a vacuum sealing section for isolating the interior of a processing chamber from the atmosphere (the atmospheric air) outside of the processing chamber. Therefore, a dielectric is required to be thick to some extent so as to withstand the atmospheric pressure when the interior of the processing chamber is reduced in pressure. In such a way, it is necessary for a dielectric to be simultaneously larger in size (area) and thicker.

There were cases, however, where a difficulty is encountered in obtaining a large size (area) and where even if a mechanical processing or the like is enabled, a cost is extremely high, according to a kind of material of a dielectric. Furthermore, with a dielectric of such a large size, a mass of a dielectric itself becomes heavy, also having led to a case where handling of the dielectric is difficult in maintenance or the like work.

In order to solve such a problem, a plasma processing apparatus has been disclosed, for example, in Japanese Patent Laying-Open No. 2000-12291 in which a dielectric is used not in one piece of a large size but in arrangement of a plurality of pieces each having a smaller area obtained by division compared with an area of a substrate to be processed, through which an electromagnetic wave is introduced into a processing chamber. FIG. 8 is a schematic sectional view of a plasma processing apparatus disclosed in Japanese Patent Laying-Open No. 2000-12291. FIG. 9 is a schematic plan view of a support frame and sealing plates of the plasma processing apparatus shown in FIG. 8. Description will be given of a plasma processing apparatus disclosed in Japanese Patent Laying-Open No. 2000-12291 according to FIGS. 8 and 9.

As shown in FIGS. 8 and 9, a plasma processing apparatus includes: a reaction chamber 121 holding a substrate 109 inside thereof; a pipe for supplying a reaction gas into reaction chamber 121; a microwave generator 125 generating a microwave to be supplied into reaction chamber 121; and a microwave waveguide 124 propagating a microwave to reaction chamber 121 from microwave generator 125 therethrough. Exhaust pipes for discharging a gas from inside of reaction chamber 121 are provided to the bottom of reaction chamber 121.

Introducing windows 122 for a microwave are formed in a region, of the top portion of reaction chamber 121, and facing waveguide 124. Introduction windows 122 are formed directly in support frame 130 as shown in FIG. 9. Opening sections are formed in an array of three rows and three columns (at nine positions in total) in support frame 130. A spacing between any two opening sections adjacent to each other is substantially constant (the opening sections are substantially uniformly arranged). Each opening section is sealed with a sealing plate 123. Sealing plate 123 is made of a dielectric such as aluminum nitride or alumina. An O-ring 126 is inserted between each sealing plate 123 and support frame 130 at a contact section thereof. A medium flow path 127 for passing cooling water is formed in support frame 130 between the opening sections. A cooling water circulating apparatus 128 is connected to medium flow path 127.

In a plasma processing apparatus with the above construction, a microwave generated from microwave generator 125 is introduced into reaction chamber 121 through waveguide 124 and sealing plates 123 arranged uniformly (at substantially equal spacings).

In a conventional plasma processing apparatus as described above, there remained the following problem. That is in a plasma processing apparatus as shown in FIGS. 8 and 9, a spacing between any two adjacent sealing plate 123 each serving as an introducing section for introducing a microwave into reaction chamber 121 is substantially constant as described above. In this case, an internal loaded condition inside of reactor chamber 121 when viewed from the input side of a microwave (an electromagnetic wave) is such that a difference in load is present between spaces closer to a side wall of reaction chamber 121 (in the outer peripheral side of reaction chamber 121) and farther from the side wall of reaction chamber 121 (in the central portion side of reaction chamber 121). In addition, there is also a case where a difference is present in a loaded condition between spaces in the above outer peripheral side and the central portion side described above in reaction chamber 121 according to an internal structure of reaction chamber 121 if the internal structure thereof is complex.

For this reason, even if a microwave in substantially the same condition can be supplied to each sealing plate 123, a case arises where a plasma formed by the microwave is distributed differently in the inside of the reaction chamber 121 according to the location of an introducing section (sealing plate 123). That is, even if the introducing sections (sealing plates 123) are arranged at a constant spacing between any two adjacent ones as described above, there is a limitation on improvement on uniformity of a plasma formed inside of reaction chamber 121. As a result, there has existed a case where difficulty is encountered in improvement on uniformity of plasma processing.

Note that an introducing section herein means an opening section for a slot antenna in a slot antenna scheme in a plasma processing apparatus using a microwave and means a dielectric section transmitting a microwave in other schemes of a plasma processing apparatus using a microwave, for example in a plasma processing apparatus of an ICP type or a helicon wave type.

In order to cope with a problem as described above, it is considered that uniformity of a plasma or plasma processing can be secured even in a case where the introducing sections are arranged at substantially equal spacings by increasing the number of introducing sections of a microwave such as sealing plates 123 of reaction chamber 121 and performing adaptation so as to change an output of microwave generator 125 according to the location of an introducing section. As to one introducing section, substantially no change occurs in a value of energy required for generating a plasma. Therefore, if the number of introducing sections increases, many high power supplies come to be required adapting to increased introducing sections in order to generate plasmas in all of the increased introducing sections. Furthermore, in this case, a necessity also arises for securing a large installation space for the many power supplies that have been increased. Moreover, complexity occurs in control of individual output adjustment for the many power supplies. For this reason, the above described measure is not realistic.

In addition thereto, in a case where a microwave having a frequency of hundreds or more of MHz is used, a waveguide is mainly adopted in order to connect a microwave generator to a reaction chamber. Such a waveguide makes its laying out complex with an increased number of introducing sections, which is different from a case of a coaxial cable used in transmitting an electromagnetic wave having a frequency lower than a microwave; therefore, a case has also arisen where easiness is degraded in a work to mount/demount the waveguide for maintenance.

### SUMMARY OF THE INVENTION

It is an object of the present invention to provide a plasma processing apparatus and a plasma processing method capable of improving uniformity of plasma processing without increasing a necessary output of a power supply.

As described above, in order to improve uniformity of plasma processing on a large-sized substrate of substantially one or more meters square, for example, in a plasma processing apparatus introducing a microwave for generating a plasma inside of a processing chamber through an introduction waveguide, a slot antenna and a dielectric from a microwave generator, installation has generally been performed of an increase in introduction scheme sets, each constituted of an introduction waveguide, a slot antenna and a dielectric, and arranged in uniformly dispersed state; or an increase in slots in a slot antenna. As a result of a study by the present inventors on the conventional practice, however, energy of a microwave introduced through each slot is decreased by the increase in introduction scheme sets or the increase in slots in a case where a total energy of a microwave introduced into a processing chamber is constant. Therefore, a microwave introduced from each slot into the processing chamber is short of energy for exciting a plasma, thereby having resulted in a case where a plasma cannot be generated normally.

Furthermore, in a case where the number of slots increases as described above, a necessity arises for increasing a total energy of a microwave in proportion to the number of slots in order to release a microwave having energy enough to excite a plasma through each of the slots. That is, a necessity arises for installation of a additional power supply having a high output to provide a microwave with sufficient energy, in correspondence with increased introduction scheme sets or increased slots.

Therefore, the present inventors conducted various experiments about a method to improve uniformity of plasma processing without accompanying installation of increased introduction scheme sets or increased slots (that is without accompanying additional installation of a power supply), which has resulted in completion of the present invention. That is, one of main reasons why a local loaded condition near each slot inside of a processing chamber is different from that near another slot is considered that conditions such as arrangement of structures inside of the processing chamber when viewed through each slot (a distance to a sidewall and a location of a substrate holder for mounting a substrate thereon when viewed through each slot) are different from those when viewed through another slot. Based on such understanding, the present inventors have found that uniformity of a plasma can be improved by optimizing arrangement of introduction scheme sets so as to be adapted to arrangement of structures inside of a processing chamber without increasing the number of introduction scheme sets. According to the findings, uniformity of plasma processing can be improved by optimizing arrangement of a smallest number of necessary introduction scheme sets while suppressing energy of a microwave introduced into the processing chamber to the lowest possible level.

A plasma processing apparatus according to the present invention, on the basis of the findings and knowledge as described above, includes: a processing chamber performing processing using a plasma; and three or more electromagnetic wave introducing parts connected to the processing chamber to introduce into the processing chamber an electromagnetic wave for driving a reaction gas supplied into the processing chamber into a plasma state, wherein of combinations of every two adjacent ones of said three or more electromagnetic wave introducing parts located in a region adjacent to the processing chamber, a distance between the two adjacent electromagnetic wave introducing parts forming one of said combinations is different from a distance between the two adjacent electromagnetic wave introducing parts forming another one of said combinations.

With such a construction adopted, electromagnetic wave introducing parts can be arranged at different spacings in agreement with an internal structure or the like of the processing chamber. Hence, even in a case where energy of a microwave supplied from each electromagnetic wave introducing part is substantially constant, uniformity of a plasma formed inside of the processing chamber can be improved by determining arrangement of electromagnetic wave introducing parts so as to suit an internal structure of the processing chamber. Therefore, uniformity of plasma processing can be improved without increasing the number of electromagnetic wave introducing parts (that is, while suppressing a power of a microwave to the lowest possible level) and furthermore, without performing complex control to alter energy of a microwave through each electromagnetic wave introducing part.

In the above plasma processing apparatus, the electromagnetic wave introducing parts may include dielectric members constituting part of an outer wall of the processing chamber; and waveguides connected to the dielectric members, respectively.

In this case, the present invention can be easily applied to a plasma processing apparatus using a microwave having a frequency of hundreds or more of MHz.

In the above plasma processing apparatus, the processing chamber may include: a wall to which the electromagnetic wave introducing part is connected; and a pair of side walls, connected to the wall, and not only extending in a direction different from a direction along which the wall extends, but also being arranged so as to face each other, wherein the distance between electromagnetic wave introducing parts in a first combination including an electromagnetic wave introducing part positioning at a point closest to one of the side walls may be different from the distance between electromagnetic wave introducing parts in a second combination not including the electromagnetic wave part positioning at a point closest to the one of the side walls.

In this case, since arrangement of the electromagnetic wave introducing parts can be determined in consideration of an influence of a side wall of the processing chamber, uniformity of a plasma in the vicinity of the sidewall can be improved. Therefore, uniformity of plasma processing can be improved.

In the above plasma processing apparatus, the processing chamber may include: a wall on which electromagnetic wave introducing part is arranged; a pair of side walls, connected to the wall, and not only extending in a direction different from a direction along which the wall extends, but also being arranged so as to face each other, wherein each of the three or more electromagnetic wave introducing parts may have a major axis in a direction substantially perpendicular to a propagation direction of electromagnetic wave therein, major axes of the three or more electromagnetic wave introducing parts may be aligned so as to substantially parallel to an extending direction of the side walls, and the three or more electromagnetic wave introducing parts may be arranged in a parallel configuration in a direction from one of the pair of side walls to the other thereof.

In this case, major axes of the electromagnetic wave introducing parts are aligned substantially in parallel to a direction along which the pair of side walls extends and not only are the electromagnetic wave introducing parts arranged in a parallel configuration between the pair of side walls, but spacings can also be determined in consideration of the side walls and the structure inside of the processing chamber. Therefore, since uniformity of a plasma can be improved, uniformity of plasma processing can be improved.

In the above plasma processing apparatus, the distance between electromagnetic wave introducing parts in the first combination including an electromagnetic wave introducing part positioning at a point closest to one of the side walls may be different from the distance between electromagnetic wave introducing parts in the second combination not including the electromagnetic wave part positioning at a point closest to the one of the side walls.

In this case, since arrangement of electromagnetic wave introducing parts is determined in consideration of an influence of the side walls with certainty, more of uniformity of a plasma in the vicinity of the side walls can be obtained. Accordingly, uniformity of plasma processing can be effectively improved.

In the above plasma apparatus, the three or more electromagnetic wave introducing parts may be arranged in substantially axial symmetry with respect to a location of an object to be processed placed inside of the processing chamber.

In this case, since arrangement of the electromagnetic wave introduction parts is determined in consideration of placement of the object to be processed, a plasma can be generated in substantially axial symmetry with respect to the object to be processed. Hence, uniformity of plasma processing on the object to be processed can be effectively improved.

In the above plasma apparatus, the electromagnetic wave introducing parts may include slot antennas disposed in propagation paths of an electromagnetic wave.

In this case, by altering locations of slots in the slot antennas, spacings between propagation paths of an electromagnetic wave (spacings between corresponding electromagnetic introducing parts) can be altered with ease. Therefore, since the above described spacings can be altered with ease so as to suit process conditions such as the processing chamber, the object to be processed, a reaction gas and others, uniformity of plasma processing can be improved with ease.

In the above plasma processing apparatus, an energy amount of an electromagnetic wave introduced into the processing chamber by one of the three or more electromagnetic introducing parts may be different from an energy amount of an electromagnetic wave introduced into the processing chamber by another of the three or more electromagnetic wave introducing parts.

In this case, by controlling not only arrangement of the electromagnetic wave introducing parts, but also an energy amount of an electromagnetic wave, uniformity of plasma processing can be improved with more certainty.

The above plasma processing apparatus may include: a gas introducing part for supplying a reaction gas into a processing chamber; a specimen table holding an object to be processed inside of the processing chamber; and an applying part applying a high frequency to the object to be processed held on the specimen table.

In the above processing apparatus, an electromagnetic wave introducing part may include at least one of a waveguide and a dielectric member disposed adjacent to the processing chamber. The dielectric member may constitute a wall surface of a processing chamber.

In this case, a location of a waveguide or a dielectric member constituting a transmission path of an electromagnetic wave is adjusted so as to be adapted to an internal structure of the processing chamber, thereby enabling easy improvement on uniformity of a plasma generated inside of the processing chamber.

In the above plasma processing apparatus, a wall surface of the processing chamber may include at least one dielectric member capable of transmitting an electromagnetic wave. The three or more electromagnetic introducing parts each may also include three or more slots formed in a slot antenna placed on a surface of the one dielectric member.

In this case, by adjusting locations of slots in an slot antenna, adjustment can be made of a local uniformity of a plasma generated in a space inside of the processing chamber facing one dielectric member constituting a wall surface of the processing chamber (part of the space inside the processing chamber). That is, finer adjustment of uniformity of a plasma is enabled.

A plasma processing method according to the present invention is a plasma processing method using a plasma processing apparatus including: a processing chamber performing a processing using a plasma; and three or more electromagnetic introducing parts connected to the processing chamber. In the above plasma processing apparatus, an electromagnetic introducing part introduces into the processing chamber an electromagnetic wave for driving a reaction gas supplied into the processing chamber into a plasma state. Of combinations of every two adjacent ones of said three or more electromagnetic wave introducing parts located in a region adjacent to the processing chamber, a distance between the two adjacent electromagnetic wave introducing parts forming one of said combinations is different from a distance between the two adjacent electromagnetic wave introducing parts forming another one of said combinations. The plasma processing method includes: a step of placing an object to be processed inside of the processing chamber; a step of supplying a reaction gas into the processing chamber; and a processing step. In the processing step, an electromagnetic wave is introduced into the processing chamber by electromagnetic wave introducing part to thereby drive the reaction gas into a plasma state. Plasma processing is performed on an object to be processed using a plasma generated in this way. Energy amounts supplied to the processing chamber from respective three or more electromagnetic wave introducing parts (for example, a power value of a microwave as an electromagnetic wave) may be substantially equal to each other. Herein, that energy amounts are substantially equal to each other means that deviations of energy amounts introduced into the processing chamber from respective three or more electromagnetic wave introducing parts from a predetermined reference value of energy amount is within ±5% of the reference value.

With such a construction adopted, a plasma processing apparatus is adopted in which electromagnetic wave introducing parts can be arranged at different spacings is adopted in agreement with a change in an internal structure of the processing chamber or the like; therefore, plasma processing (a processing step) can be implemented in a condition in which uniformity of a plasma generated inside of the processing chamber is improved. Therefore, uniformity of plasma processing can be improved on an object to be processed.

In the above plasma processing method, an energy amount of an electromagnetic wave introduced into the processing chamber by one electromagnetic wave introducing part among three or more electromagnetic wave introducing parts in the processing step may be different from an energy amount of an electromagnetic wave introduced into the processing chamber by another electromagnetic wave introducing part among three or more electromagnetic wave introduction parts.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view showing a first embodiment of a plasma processing apparatus according to the present invention;

FIG. 2 is a schematic sectional view taken along line II-II of FIG. 1;

FIG. 3 is a schematic plan view of a chamber cover when viewed in the direction of an arrow of FIG. 12;

FIG. 4 is a schematic sectional view showing a second embodiment of a plasma processing apparatus according to the present invention;

FIG. 5 is a schematic sectional view taken along line V-V of FIG. 4;

FIG. 6 is a schematic sectional view showing a third embodiment of a plasma processing apparatus according to the present invention;

FIG. 7 is a schematic sectional view for describing a plasma processing apparatus used in an example of the present invention;

FIG. 8 is a schematic sectional view of a plasma processing apparatus disclosed in Japanese Patent Laying-Open No. 2000-12291; and

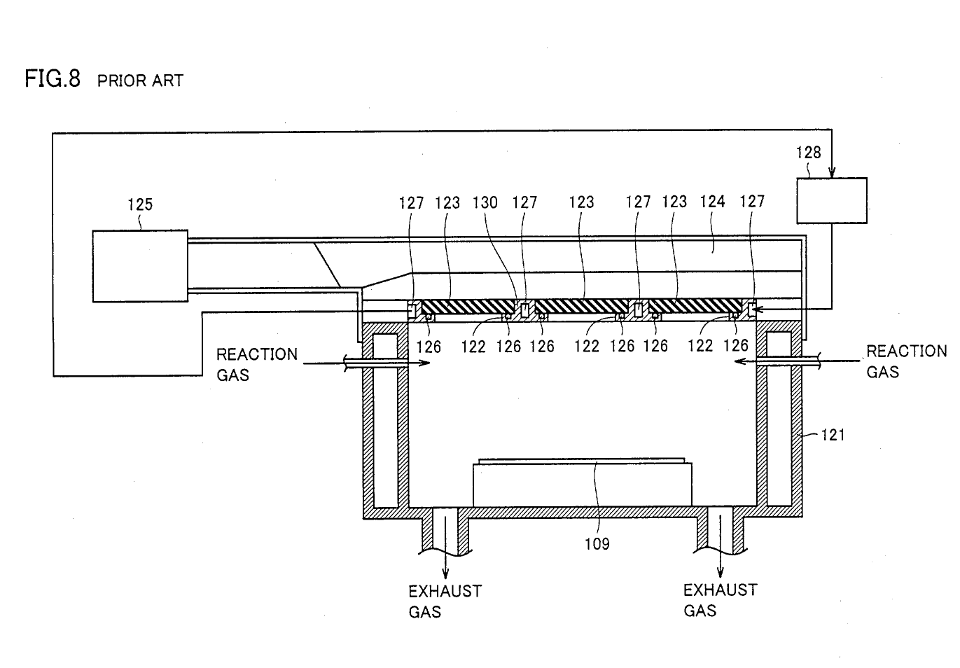

FIG. 9 is a schematic plan view of a support frame and sealing plates of the plasma processing apparatus shown in FIG. 8.

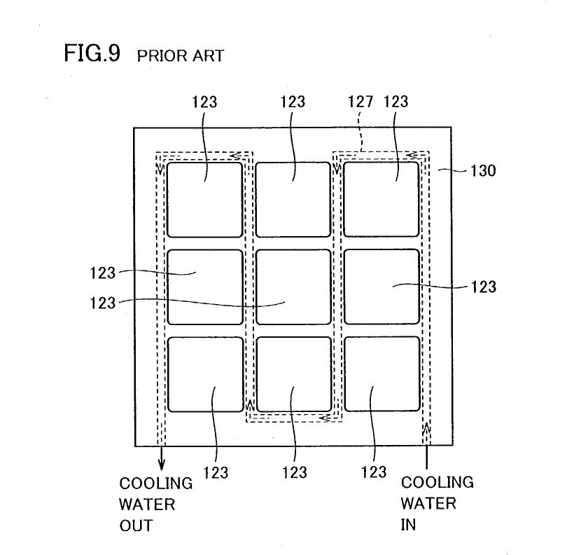

### DESCRIPTION OF THE PREFERRED EMBODIMENTS

Description will be given of embodiments of the present invention based on the accompanying drawings below. Note that the same or corresponding constituents are denoted by the same reference numerals in the following figures; therefore, none of descriptions thereof will be repeated.

### First Embodiment

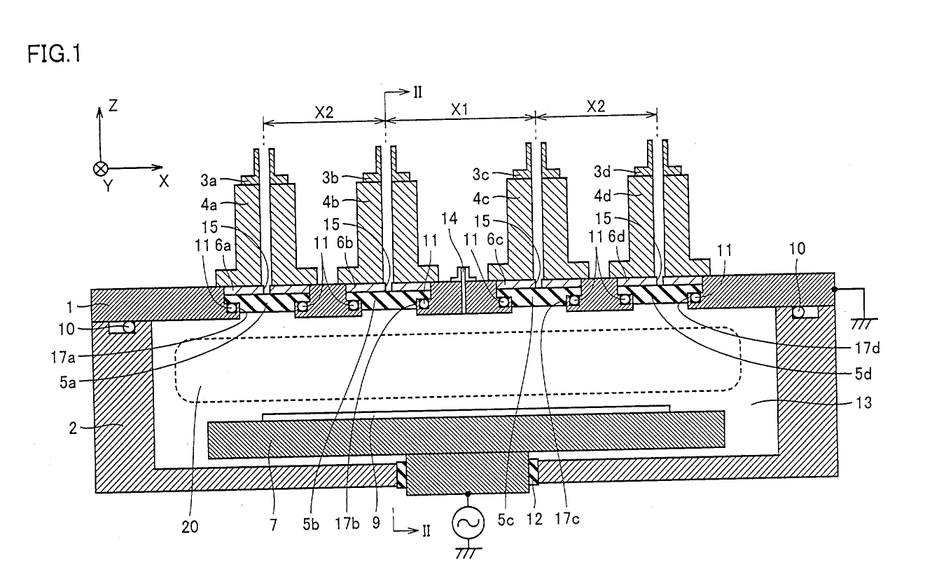

Referring to FIGS. 1 to 3, description will be given of a first embodiment of a plasma processing apparatus according to the present invention.

As shown in FIGS. 1 to 3, a plasma processing apparatus includes: a chamber body 2 having an opening section at the top thereof; and a chamber cover 1 placed so as to cover the opening section of chamber body 2. A processing chamber is constituted of chamber body 2 and chamber cover 1. Chamber cover 1 and chamber body 2 are sealed with a gasket 10 at a contact section therebetween. Chamber cover 1 is grounded.

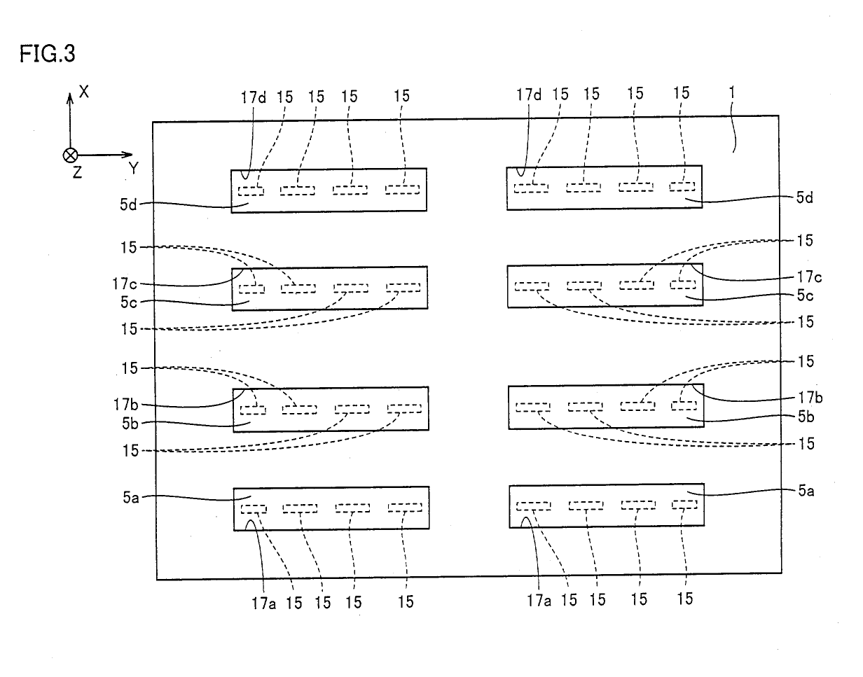

Opening sections 17a to 17d are formed in chamber cover 1 as a wall section at eight positions as shown in FIG. 3. Dielectric members 5a to 5d are inserted into and fixed to opening sections 17a to 17d, respectively. As materials of dielectric members 5a to 5d, there can be used silicon oxide (SiO₂), aluminum oxide (Al₂O₃), aluminum nitride (AlN) and the like. Gaps between chamber cover 1 and respective dielectric members 5a to 5d are sealed with gaskets 11.

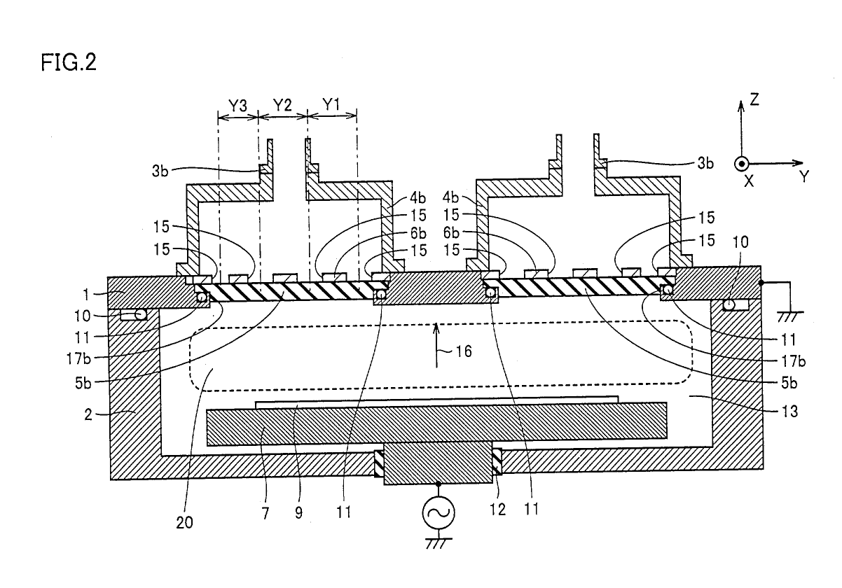

Slot antenna plates 6a to 6d are, as shown in FIG. 1, placed as slot antennas on dielectric members 5a to 5d. Slot antenna plates 6a to 6d all have shapes substantially similar to each another. Description will be given of slot antenna plate 6b as an example in a concrete manner. Four slots 15 are, as shown in FIG. 2, formed in slot antenna plate 6b placed on dielectric member 5b.

As shown in FIG. 1, introduction waveguides 4a to 4d are placed on slot antenna plates 6a to 6d. Electromagnetic wave introducing parts are constituted of introduction waveguides 4a to 4d, slot antenna plates 6a to 6d and dielectric members 5a to 5d. It is sufficient that there are three or more electromagnetic wave introducing parts. The number of the electromagnetic wave introducing parts is preferably four or more. Introduction waveguides 4a to 4d are, as can be seen from FIGS. 1 and 2, formed so as to extend in a direction substantially in parallel to Y axis (the electromagnetic introducing part has a major axis perpendicular to a propagation direction of an electromagnetic wave (a microwave) propagated in introduction waveguides 4a to 4d and substantially in parallel to Y axis). The major axis of the electromagnetic wave introducing part (a microwave introducing section), as can be seen from FIG. 1, extends substantially in parallel to a direction along which side walls of chamber body 2 extend (Y axis direction) while the electromagnetic wave introducing part are also arranged in a parallel configuration in a direction (the X axis direction) substantially perpendicular to a direction (the Y axis direction) along which the major axis extends.

Waveguides 3a to 3d are placed on introduction waveguides 4a to 4d. Waveguides 3a to 3d are connected to a magnetron which is not shown. To be concrete, waveguides 3a to 3d are connected to the magnetron through a microwave solid circuit, which is not shown, such as an isolator, an automatic matching unit, and a straight waveguide, a corner waveguide, a tapered waveguide and a branch waveguide according to JIS standards. Formed substantially in the central portion of chamber cover 1 is a gas introduction path 14 as a gas introducing part for introducing a reaction gas for use in plasma processing into a chamber interior 13.

A substrate holder 7 as a specimen table for holding a substrate 9 to be processed is placed in chamber interior 13 at the bottom of chamber body 2 so as to face chamber cover 1. A pedestal for supporting substrate holder 7 is disposed below substrate holder 7. The pedestal is disposed so as to penetrate into a bottom wall of chamber body 2. An insulator 12 is disposed between the pedestal and the bottom wall of chamber body 2. Substrate holder 7 is electrically connected to a high frequency power supply as an applying part through the pedestal.

Chamber interior 13 is held in a vacuum state at a pressure of the order of 1×10⁻⁴ Pa to 1×10⁻⁵ Pa by discharging the atmospheric gas inside chamber interior 13 by means of a vacuum pump which is not shown. Note that, though not shown, temperature adjusting mechanisms for holding temperatures in corresponding ranges are provided to chamber cover 1, chamber body 2 and substrate holder 7, respectively. A temperature adjusting mechanism includes a heating member such as an electric heater, a cooling jacket for circulating a cooling medium or the like.

As shown in FIG. 1, distances between sets of slots 15 as an electromagnetic wave introducing part formed in each of slot antenna plates 6a to 6d in the X axis direction (a distance between electromagnetic wave introducing parts in combination of adjacent electromagnetic wave introducing parts in a region adjacent to chamber body 2) are set in a manner such that a distance X1 between sets of slots 15 in the central portion of chamber cover 1 of the plasma processing apparatus (a distance X1 between electromagnetic wave introducing parts in combination of adjacent electromagnetic wave introduction parts excluding electromagnetic wave introducing parts closest to a side wall of chamber body 2) is different from a distance X2 between sets of slots 15 in a portion located in an end side of chamber cover 1 (an side wall side of chamber body 2) (a distance X2 between electromagnetic wave introducing part in combination of adjacent electromagnetic wave introducing parts including electromagnetic wave introducing parts closest to a side wall of chamber body 2). That is, as shown in FIG. 1, distance X1 between the center of slot 15 formed in slot antenna 6b and the center of slot 15 formed in slot antenna 6c is larger than distance X2 between the center of slot 15 formed in slot antenna 6a and the center of slot 15 formed in slot antenna 6b or distance X2 between the center of slot 15 formed in slot antenna 6c and the center of slot 15 formed in slot antenna 6d.

Furthermore, as shown in FIG. 2, distances between the centers of four slots 15 as electromagnetic wave introducing parts formed in slot antenna plate 6b are so as to take respective different values in the Y axis direction in the figure. That is, in slot antenna plate 6b shown in FIG. 2, a distance between the center of slot 15 (a first slot) located at the rightmost end in the figure (a region farthest from a side wall of chamber body 2) and the center of slot 15 (a second slot) disposed adjacent thereto on the left side thereof is indicated by distance Y1. A distance between the center of the second slot and the center of slot 15 (a third slot) disposed adjacent thereto on the left side thereof is indicated by distance Y2. A distance between the center of the third slot and the center of slot 15 (a fourth slot) disposed adjacent thereto on the left side of the third slot is indicated by distance Y3. Distances Y1 to Y3 are different from each other. Note that the number of slots 15 formed in slot plate 6b is preferably three or more, more preferably four or more.

Then, description will be given of operations of the plasma processing apparatus shown in FIGS. 1 to 3 in a case of being used as a dry etching apparatus.

Substrate 9 to be processed in etching is, as shown in FIG. 1, at first placed on substrate holder 7 as a step of placing an object to be processed inside of the processing chamber. An atmospheric gas is discharged in chamber interior 13 using an exhauster (not shown) till chamber interior 13 creates a vacuum state as described above. Then, a process gas as a reaction gas is introduced into chamber interior 13 through gas introduction path 14 (see FIG. 1) as a step of supplying the reaction gas into the processing chamber. Examples of the process gases include a mixed gas of CF₄ and oxygen gas (O₂), chlorine (Cl₂) gas and the like.

Then, a microwave having a frequency of 2.45 GHz is generated from a magnetron not shown. The microwave is radiated into chamber interior 13 through a microwave solid circuit, not shown, including an isolator, an automatic matching unit, a straight waveguide, a corner waveguide, a tapered waveguide, a branch waveguide and the like according to JIS standards and furthermore through waveguides 3a to 3d, through introduction waveguides 4a to 4d, through slots 15 in slot antenna plates 6a to 6d and through dielectric members 5a to 5d. The above described process gas is given energy by the microwave to thereby generate an ionized gas (plasma 20). Etching is performed on substrate 9 on substrate holder 7 using plasma 20. In such a way, a processing step is implemented. Note that as substrate 9, there can be used, for example, a substrate in which a film or a layered film made of one or more of materials including a metal such as aluminum and an insulator such as silicon oxide is formed on a substrate made of glass and a resist pattern such as wiring and contact holes is formed on the film.

Summarizing a characteristic construction of an etching method as one example of a plasma processing method described above according to the present invention, an etching method according to the present invention is an etching method (a plasma processing method) using a plasma processing apparatus including: a chamber including chamber body 2 and chamber cover 1 as a processing chamber performing a processing using a plasma; introduction waveguides 4a to 4d as three or more electromagnetic wave introducing parts connected to the chamber; slot antenna plates 6a to 6d; and dielectric members 5a to 5d.

Note that three or more slots 15, more preferably four or more slots 15 serving as electromagnetic wave introducing parts are formed in each of slot antenna plates 6a to 6d as slot antennas. In the above plasma processing apparatus, electromagnetic wave introducing parts (introduction waveguides 4a to 4d, slot antenna plates 6a to 6d and dielectric members 5a to 5d) is a part introducing an electromagnetic wave for rendering a process gas as a reaction gas supplied into chamber interior 13 to be in a plasma state into inside of the chamber. Of combinations of every two adjacent ones of said three or more electromagnetic wave introducing parts located in a region adjacent to the processing chamber (for example, a region in which slot antenna plates 6a to 6d are arranged on chamber cover 1 or a region where introduction waveguides 4a to 4d are arranged thereon), a distance between the two adjacent electromagnetic wave introducing parts (for example, sets of slots formed in slot antenna plates 6a and 6b) forming one of said combinations (for example, as shown in FIG. 1, a distance X2 between the center of slot 15 formed in slot antenna plate 6a and the center of slot 15 formed in antenna plate 6b) is different from a distance between the two adjacent electromagnetic wave introducing parts (for example, sets of slots 15 formed in slot antenna plates 6b and 6c) forming another one of said combinations (for example, as shown in FIG. 1, a distance X1 between the center of slot 15 formed in slot antenna plate 6b and the center of slot 15 formed in slot antenna plate 6c).

Furthermore, as shown in FIG. 2, in a case where slot 15 formed in one slot antenna plate 6b corresponds to the above electromagnetic wave introducing part, of combinations of every two adjacent ones of said three or more electromagnetic wave introducing parts (each having four slots 15 formed in slot antenna plate 6b) located in a region adjacent to the processing chamber (a region where slot antenna plate 6b is provided on chamber cover 1), a distance Y1 between the two adjacent electromagnetic wave introducing parts (slots 15) forming one of said combinations is different from a distance Y2 or Y3 between the two adjacent electromagnetic wave introducing parts (slots 15) forming another one of said combinations.

The above etching method includes: a step of placing substrate 9 as an object to be processed inside of the chamber; a step of supplying a process gas as a reaction gas into the chamber; and a processing step. In the processing step, a microwave as an electromagnetic wave is introduced into the chamber by electromagnetic wave introducing parts (introduction waveguides 4a to 4d, slot antenna plates 6a to 6d and dielectric members 5a to 5d) to thereby, render the process gas to be in a plasma state. Plasma processing such as etching processing is performed on substrate 9 using a plasma generated in this way. Power values of a microwave supplied into chamber interior 13 from respective sets of introduction waveguides 4a to 4d, slot antenna plates 6a to 6d and dielectric members 5a to 5d may be substantially equal to each other.

With such a construction adopted, since there is used a plasma processing apparatus in which sets of introduction waveguides 4a to 4d, slot antenna plates 6a to 6d and dielectric members 5a to 5d or slots 15 formed in slot antenna plates 6a to 6d are arranged at different spacings, adapting to internal structure of the processing chamber or the like, etching can be performed in a state of plasma 20 improved on uniformity thereof generated in chamber interior 13. Therefore, improvement can be achieved on uniformity of etching as a plasma processing on substrate 9.

Note that in the processing step of the above etching method, a power value of a microwave introduced into chamber interior 13 by one of the sets of introduction waveguides 4a to 4d, slot antenna plates 6a to 6d and dielectric members 5a to 5b as three or more electromagnetic wave introducing parts may be different from a power value of a microwave introduced into chamber interior 13 by another of the sets constituting the three or more electromagnetic wave introducing parts.

As shown in FIG. 1, in the plasma processing apparatus according to the present invention, distances X1 and X2 each between the centers of slots 15 adjacent to each other in the X axis direction are different between values thereof in the central portion and the outer peripheral portion. That is, consideration is given to a change in a plasma state caused by the presence of a side wall of chamber body 2 and microwave introducing sections as electromagnetic wave introducing parts constituted of introduction waveguides 4a to 4d, slot antenna plates 6a to 6d and dielectric members 5a to 5d are optimally arranged so as to eventually attain a uniform distribution of a plasma generated by a microwave radiated into chamber interior 13 from a plurality of slots 15. Even in a case where energy of a microwave supplied into chamber interior 13 from the microwave introducing sections are controlled at substantially uniform levels in this way, arrangement of the microwave introducing sections are determined so as to suit a structure of chamber interior 13 (for example, in consideration of an influence of a side wall of chamber body 2); therefore, uniformity of a plasma can be improved in chamber interior 13. Therefore, uniformity of plasma processing can be improved without increasing the number of microwave introducing sections (while suppressing a power of an introduced microwave to the lowest possible level) and without performing complex control that energy of a microwave at each of the microwave introducing sections is changed.

Furthermore, as shown in FIG. 2, distances Y1 to Y3 between the centers of slots 15 in slot antenna plate 6b are set at respective optional values to thereby improve uniformity of a plasma in the Y direction in a similar way. Furthermore, at this time, by a change in arrangement of slots 15 in each of slot antenna plates 6a to 6d (see FIG. 1), distances Y1 to Y3 between the centers of slots 15 in the plasma processing apparatus can be changed with comparative ease.

Note that while, as shown in FIG. 2, distances Y1 to Y3 between the centers of slots 15 are changed, uniformity of a plasma generated can be maintained at a higher level even in a case where distances between the centers of slots 15 are uniform if a sufficient number of slots 15 can be disposed in the Y direction. Furthermore, while, in the plasma processing apparatus shown in FIGS. 1 to 3, slot antenna plates 6a to 6d are placed between introduction waveguides 4a to 4d and dielectric members 5a to 5d, slot antenna plates 6a to 6d may be placed on surfaces of dielectric members 5a to 5d facing chamber interior 13.

Moreover, in the plasma processing apparatus shown in FIGS. 1 to 3, microwave introducing sections including introduction waveguides 4a to 4d, dielectric members 5a to 5d and slot antenna plates 6a to 6d are arranged in axial symmetry with respect to the central portion of substrate 9. In this case, since arrangement of the microwave introducing sections are determined in consideration of a location of substrate 9 to be processed, a distribution of a generated plasma can be substantially in axial symmetry with respect of the center of substrate 9. Therefore, uniformity of plasma processing on substrate 9 can be effectively improved.

Furthermore, in the plasma processing apparatus shown in FIGS. 1 to 3, distances X1 or X2 shown in FIG. 1 can be altered by altering arrangement of slots 15 in slot antenna plates 6a to 6d, for example, in the X axis direction of FIG. 1. Moreover, distances Y1 to Y3 can be altered with ease by altering locations of slots 15 in the Y axis direction shown in FIG. 2. Therefore, since distances X1, X2 and Y1 to Y3 can be altered with ease so as to suit processing conditions and a structure of chamber interior 13, uniformity of plasma processing can be improved with ease.

In addition, the present invention can be applied to various kinds of plasma processing apparatuses other than a plasma processing apparatus using slot antennas 6a to 6d as shown in FIGS. 1 to 3. For example, in a plasma processing apparatus using a microwave generated with ECR (Electron Cyclotron Resonance) or the like, an ICP (Inductively Coupled Plasma) plasma apparatus with a plurality of introducing sections introducing an electromagnetic wave other than a microwave and a helicon wave plasma apparatus as well, uniformity of plasma processing can be enhanced by adopting different spacings between introducing sections for an energy source for generating a plurality of plasmas. Besides, the present invention can also be applied to processing apparatuses using a plasma other than a dry etching apparatus as described above, for example an ashing apparatus, a CVD (Chemical Vapor Deposition) apparatus, a sputtering apparatus and the like.

### Second Embodiment

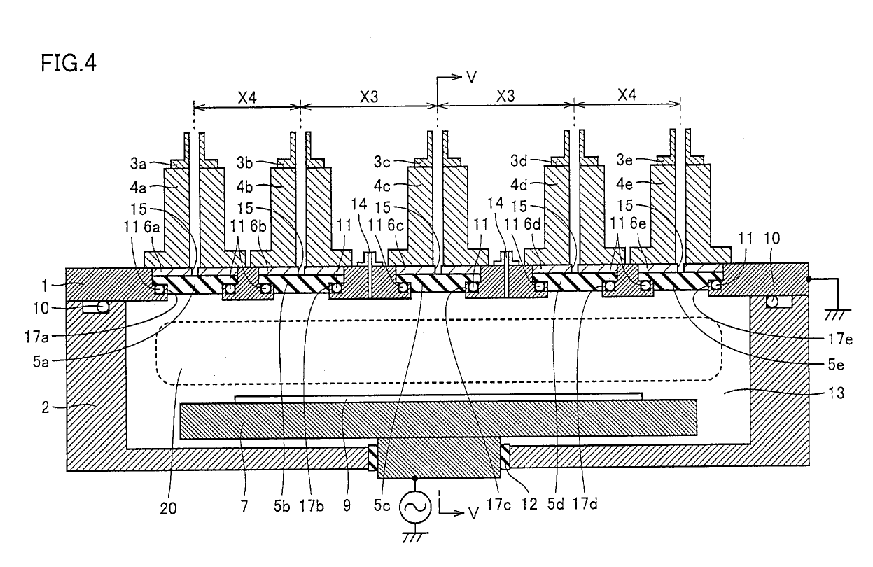

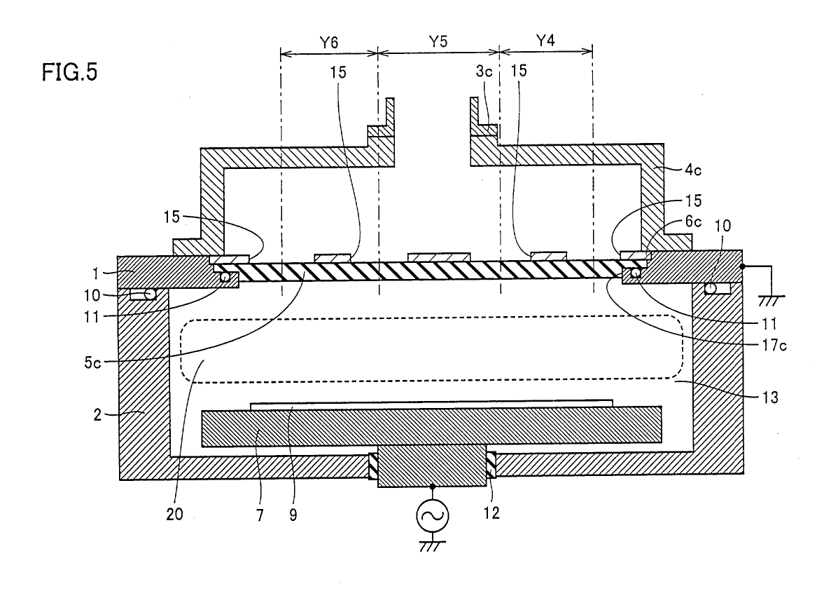

Referring to FIGS. 4 and 5, description will be given of a second embodiment of a plasma processing apparatus according to the present invention. Note that FIG. 4 corresponds to FIG. 1.

While, as shown in FIGS. 4 and 5, a plasma processing apparatus has a structure basically similar to the plasma processing apparatus shown in FIGS. 1 to 3, it is different in a structure of a section through which a microwave is introduced into chamber interior 13. That is, in the plasma processing apparatus shown in FIGS. 4 and 5, opening sections 17a to 17e are formed at five sites in chamber cover 1. Dielectric members 5a to 5c are disposed inside opening sections 17a to 17e. Slot antenna plates 6a to 6e in each of which four slots 15 are formed are placed on dielectric members 5a to 5e. Introduction waveguides 4a to 4e are placed on respective slot antennas 6a to 6e. Waveguides 3a to 3e are placed on introduction waveguides 4a to 4e. Microwave introducing sections are constituted of respective sets of dielectric members 5a to 5e, slot antenna plates 6a to 6e and introducing waveguides 4a to 4e. To be concrete, for example, one microwave introducing section is constituted of dielectric member 5a, slot antenna plate 6a and introduction waveguide 4a.

While in the plasma processing apparatus shown in FIGS. 1 to 3, eight microwave introducing sections are arranged in a matrix in chamber cover 1, five microwave introducing sections are arranged in a parallel configuration (so as to extend in parallel to the major axis) in the plasma processing apparatus shown in FIG. 4. As shown in FIG. 4, a distance X3 between adjacent microwave introducing sections disposed in the vicinity of the central portion of chamber interior 13 is different from a distance X4 between microwave introducing sections located in the outer peripheral side of chamber interior 13. To be concrete, a distance X3 between the center of slot 15 formed in slot antenna plate 6b and the center of slot 15 formed in slot antenna plate 6c is set to be larger than distance X4 between the center of slot 15 formed in slot antenna plate 6a located in the outer peripheral side and the center of slot 15 formed in slot antenna plate 6b.

With such a construction adopted, since arrangement of microwave introducing sections are determined in consideration of an influence of a side wall of chamber body 2, uniformity can be improved to a higher level than in a case where distances X3 and X4 are the same as each other, which is similar to the first embodiment of the present invention.

Furthermore, as shown in FIG. 5, each of distances Y4 to Y6 between the centers of slots 15 formed in slot antenna plate 6c may be set differently from the others. In this case as well, there can be obtained an effect similar to that of the first embodiment of a plasma processing apparatus according to the present invention.

Note that in the plasma processing apparatuses shown in FIGS. 4 and 5, microwave introducing sections constituted of dielectric members 5a to 5e, slot antenna plates 6a to 6e, introducing waveguides 4a to 4e and the like are substantially axial symmetry with respect to the central axis (an axis shown with a line segment V-V) extending in a direction normal to chamber cover 1 in the central portion (the central portion of substrate 9) of the sectional view of the plasma processing apparatus. With such a construction adopted, there can be obtained a plasma with substantially uniformity relative to substrate 9 placed substantially in the central portion of chamber interior 13. Therefore, uniform plasma processing on substrate 9 can be performed.

Uniformity of processing can be secured by properly altering the numbers of introducing waveguides 4a to 4e, slot antenna plates 6a to 6e and the like according to a size of substrate 9 to be processed, a shape of substrate 9 in a plan view such as a ratio of a height to a width, a process gap, a required target value of uniformity of processing, the number of slots 15 formed in slot antenna plates 6a to 6e (the number of slot openings) or the like.

### Third Embodiment

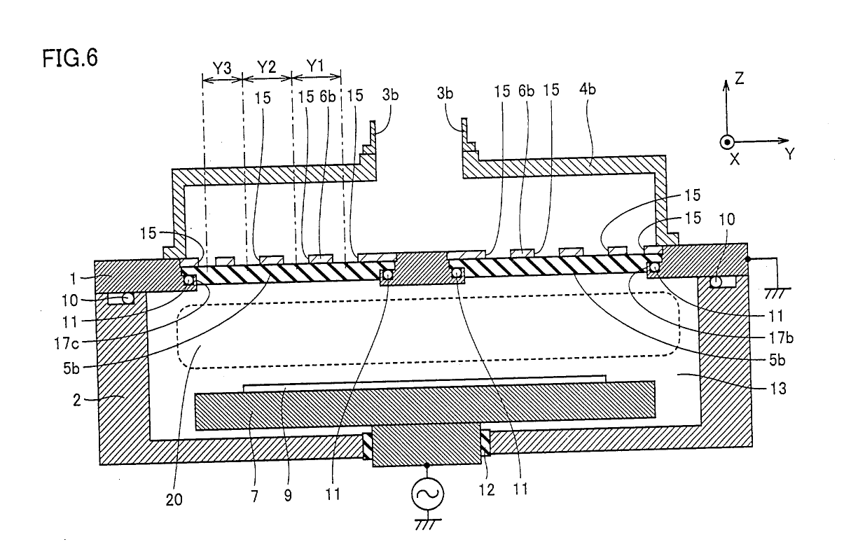

Referring to FIG. 6, description will be given of a third embodiment of a plasma processing apparatus according to the present invention. Note that FIG. 6 corresponds to FIG. 2. That is, a section shown in FIG. 6 corresponds to a section taken along line II-II of FIG. 1.

While, as shown in FIG. 6, the plasma processing apparatus has a structure basically similar to that of the plasma processing apparatus shown in FIGS. 1 to 3, it is different in structures of introducing waveguide 4b and waveguide 3b. Note that a sectional shape of the plasma processing apparatus shown in FIG. 6 on a X-Z plane view is basically similar to that of the plasma processing apparatus shown in FIG. 1.

In the plasma processing apparatus shown in FIGS. 1 to 3, introducing waveguides 4a to 4d are provided to respective dielectric members 5a to 5b (see FIG. 1). On the other hand, in the plasma processing apparatus shown in FIG. 6, two dielectric members 5b are disposed under one introducing waveguide 4b. That is, one introducing waveguide 4b is formed for two dielectric members 5b.

With such a construction adopted, not only can there be obtained an effect similar to that of the plasma processing apparatus according to the first embodiment, but the number of introducing waveguides 4a to 4d (see FIGS. 1, 2 and 6) provided to dielectric members 5a to 5d (see FIG. 1) can be reduced to be less than in the plasma processing apparatus in the first embodiment of the present invention. Hence, in a case where a plasma processing apparatus corresponding to a large-sized substrate 9, the number of waveguides from a microwave generator and the number of branches can be less than in the case of the plasma processing apparatus shown in FIGS. 1 to 3. Therefore, a construction of a plasma processing apparatus can be made simpler and more convenient.

Note that a plasma processing apparatus described in FIG. 6 can also be considered to be an example modification of the second embodiment of the plasma processing apparatuses shown in FIGS. 4 and 5. That is, the plasma processing apparatus shown in FIG. 6 can also be regarded to have a construction obtained by dividing dielectric member 5c (see FIG. 5) shown in a section of FIG. 5 into halves.

With such a consideration applied, an area of each of dielectric elements 5b (see FIG. 6) in the plasma processing apparatus shown in FIG. 6 can be smaller by dividing dielectric member 5c (see FIG. 5) compared with the plasma processing apparatuses shown in FIGS. 4 and 5. As a result, a stress can be reduced that is imposed on each dielectric member 5b playing a role as a vacuum sealing member of chamber interior 13. Therefore, dielectric members 5b (see FIG. 6) can be thinner than dielectric member 5c shown in FIG. 5c.

Furthermore, since by dividing dielectric member 5b as shown in FIG. 6, an area of each of openings 17b of chamber cover 1 can be smaller, a rigidity thereof can be improved. As a result, when chamber interior 13 is vacuumed, a deformation of chamber cover 1 caused by an atmospheric pressure imposed on chamber cover 1 can be made small.

In a case where a plasma processing apparatus is scaled up in company with transition to a large-sized substrate 9, the plasma processing apparatus can be easily reconstructed so as to be adapted to large-sized substrate 9 by increasing the number of dielectric members 5b obtained by division with an original construction having dielectric members 5b obtained by division adopted. Furthermore, a fabrication cost of dielectric member 5b obtained by division (small in size) in such a way can be suppressed at a cost lower than a cost of a relatively large-sized dielectric member 5c as shown in FIG. 5. Therefore, a construction of a plasma processing apparatus having the construction as shown in FIG. 6 is preferable as a construction of a plasma processing apparatus corresponding to a large-sized substrate 9.

Note that while in the plasma processing apparatus shown in FIG. 6, two dielectric members 5b are provided to one introducing waveguide 4b, three or more dielectric members 5b may be provided to one introduction waveguide 4b. In this case, an effect similar to the former case can also be obtained.

Furthermore, while in the plasma processing apparatus shown in the first to third embodiments, an energy amount of a microwave introduced into chamber interior 13 from each of microwave introducing sections may be substantially the same as those of the others, each of energy amounts introduced from respective microwave introducing sections may be different from those of the others. With such a construction adopted, an energy amount of a microwave can be used as a control parameter, thereby enabling improvement on uniformity of plasma processing with more of certainty.

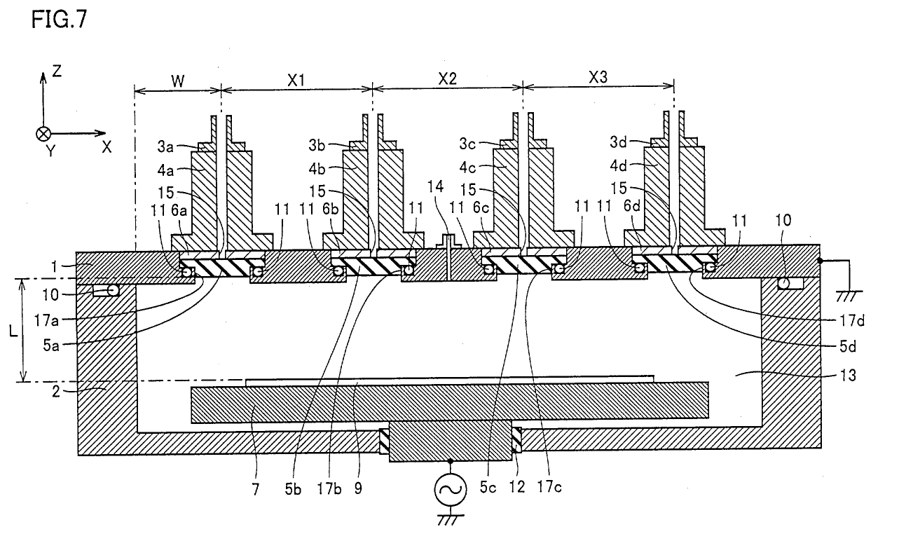

In order to confirm an effect of a plasma processing apparatus according to the present invention, the following experiments were conducted. A plasma processing apparatus as shown in FIG. 7 was prepared at first.

The plasma processing apparatus shown in FIG. 7 has a construction basically similar to that of the plasma processing apparatus shown in FIGS. 1 to 3. That is, a plasma processing apparatus shown in FIG. 7, similarly to the plasma processing apparatus shown in FIG. 1, has a structure in axial symmetry with respect to the center line thereof in the X axis direction. In the plasma processing apparatus shown in FIG. 7, experiments to confirm distributions of plasma processing (processing distributions) were conducted in respective cases where there were used microwave introducing sections constituted of introduction waveguides 4a to 4d, slot antenna plates 6a to 6d, and dielectric members 5a to 5d, arranged so as to have different spacings therebetween in various ways in the outer peripheral portion and the central portion of the chamber.

As a first experiment, a microwave was introduced into chamber interior 13 only with a microwave introducing section in the outermost side (corresponding to dielectric member 5a, slot antenna plate 6a and introduction waveguide 4a in FIG. 7) of 150 mm in distance W from a side wall of chamber body 2. A plasma was generated in chamber interior 13 with the introduced microwave to perform etching.

As a second experiment, a microwave was introduced into chamber interior 13 only with a microwave introducing section at the second place from the outermost side (corresponding to dielectric member 5b, slot antenna plate 6b and introduction waveguide 4b in FIG. 7) of 270 mm in distance (distance W+distance X1) from the side wall of chamber body 2. A plasma was generated in chamber interior 13 with the introduced microwave to perform etching in a similar way.

As a third experiment, etching was likewise performed by introducing a microwave only with a microwave introducing section at the third place from the outermost side (corresponding to dielectric member 5c, slot antenna plate 6c and introduction waveguide 4c in FIG. 7) of 390 mm in distance from the side wall of chamber body 2. Note that a distance from a side wall on the right side of chamber body 2 in FIG. 7 to the microwave introducing section was 390 mm or more.

In the above first to third experiments, measurement was conducted on a film thickness (a thickness of an etched film) on each of substrate surfaces on which etching was performed, wherein a normal distribution was used as an approximation of each of the empirical distributions. As a result, standard deviations a of the results in the first to third experiments were 100 mm for the first experiment, 137 mm for the second experiment and 135 mm for the third experiment. Note that the values 137 mm and 135 mm of standard deviations of the second and third experiments are different from each other but still within the error; therefore, the values of standard deviations are regarded as being subatantially equal.

From the results of the first to third experiments, a standard deviation σ of thickness of the etched film as a result of processing is considered to show a dependency on a distance from a side wall, in a region (in the vicinity of the side wall) in which a distance from the side wall of chamber body 2 to a microwave introducing section in measurement is equal to or less than a threshold value. On the other hand, it is considered that substantially no dependency on a distance from the side wall exists to obtain a standard deviation at a substantially constant value, in a region where a distance from a side wall of chamber body 2 to a microwave introducing section in measurement is larger than the threshold value (in a region (the central portion) farther from the side wall than a portion in the vicinity of the side wall). The threshold value is considered to be in the numerical range of from 150 mm to 270 mm in the above experiments performed in the plasma processing apparatus. Note that conditions in the above experiments for processing were such that a power of a microwave is 3000 W, a reaction gas used was Cl₂ (chlorine gas) and a film to be etched was an aluminum (Al) film.

A threshold value described above is also different according to a construction factor such as a shape of a chamber of a plasma processing apparatus or a distance L between the lower surfaces of dielectric members 5a to 5d and the top surface of substrate 9, a material of the side wall of chamber body 2, a pressure and composition of a reaction gas, energy of an introduced microwave, a material to be etched, or the like. Furthermore, a chance also arises where a standard deviation σ of etching in a case of a microwave introducing section located in the vicinity of a side wall of chamber body 2 in use is larger than a standard deviation σ of etching in a case of a microwave introducing section located in the central portion in use. Furthermore, a ratio of a change in standard deviation σ relative to a distance from a side wall of a microwave introducing section located in the vicinity of the side wall is also considered to be different according to a processing condition or the like. For example, a case arises where a ratio of increase or decrease of a standard deviation described above in a region extremely close to a side wall is different from the ratio in the vicinity of a threshold value.

While in each of the first to third experiments, there are shown the results in a case where energy of a microwave was introduced through only one microwave introducing section, even in a case where energy of a microwave are introduced through all the microwave introducing sections installed in the plasma processing, it is considered that a processing result is different according to a distance from a side wall of chamber body 2 while there occurs a change in a region where a plasma is generated in chamber interior 13.

Then, evaluation was performed on uniformity of plasma processing based on data of the microwave introducing sections obtained in the first to third experiments described above. That is, a plurality of pieces of data in processing results by individual microwave introducing sections were superimposed according to locations of introduction waveguides 4a to 4d in the X direction shown in FIG. 7 to thereby, perform uniformity of the processing results.

As a result, uniformity of the processing results in a case where microwave introducing sections are arranged at equal spacings in the X direction (in a case where distances X1=X2=X3 in FIG. 7) is inferior to uniformity of the processing results in a case where microwave introducing sections are arranged so that distances X1, X2 and X3 in FIG. 7 are different from each other. That is, it was shown that, in plasma processing apparatuses each provided with the same number of microwave introducing sections, arrangement of the microwave introducing sections at different spacings according to a shape of a processing chamber or the like is more improved in uniformity of plasma processing than arrangement of the microwave introducing sections at equal spacings. Detailed description will be given thereof below.

A length of substrate 9 to be processed shown in FIG. 7 is 930 mm. Evaluation on uniformity of processing was performed in a case where uniformity of processing was aimed to be improved on a substrate of such a large size with the smallest possible number of introduction waveguides 4a to 4d (that is the smallest possible number of microwave introducing sections), for example in a case where four introduction waveguides 4a to 4d were used as shown in FIG. 7.

Arrangement of four introduction waveguides 4a to 4d with the best uniformity of processing wherein a power introduced through each of introduction waveguides 4a to 4d was controlled at a constant value (a power ratio=1 to 1 between any two) was sought in cases where and four introduction waveguides 4a to 4d are disposed at equal spacings (X1=X2=X3), and where spacings between introduction waveguides located in the outer peripheral portion of chamber cover 1 (a distance X1 between slots 15 of respective introduction waveguides 4a and 4b and a distance X3 between slots 15 of respective introduction wavegides 4c and 4d) is different from a spacing between introduction waveguides located in the central side (a distance X2 between slots 15 of respective introduction waveguides 4b and 4c) (where the value of X1 and X3 are different from the value of X2).

As a result, arrangement with the best uniformity of processing in a case where introduction waveguides 4a to 4d were disposed at equal spacings was that in which X1=X2=X3=280 mm in FIG. 7. This arrangement is hereinafter referred to as Arrangement 1. On the other hand, arrangement with the best uniformity of processing in a case where introduction waveguides 4a to 4d take different spacings was that in which distance X2=320 mm and distances X1=X3=272 mm shown in FIG. 7. This arrangement is hereinafter referred to as Arrangement 2.

In Arrangement 1, uniformity of processing was ±10.5%. On the other hand, in Arrangement 2, uniformity of processing was ±7.6%. Note that plasma processing here was etching. Definition of uniformity is such that etching amounts are measured at 108 sites on a substrate surface subjected to etching, the maximum value and the minimum value are extracted from data to obtain a value, as the definition of uniformity, in percentage obtained by dividing a half of a difference between the maximum value and the minimum value with a central value (that is, a half of the sum of the maximum value and the minimum value). An expression of definition of the uniformity is ((the maximum value−the minimum value)/(the maximum value+the minimum value))×100%.

Introduction waveguides 4a to 4d disposed at different spacings is, in this way, more improved in uniformity by about 28% than introduction waveguides 4a to 4d disposed at equal spacings in a case where a power (an energy amount) introduced through each of introduction waveguides 4a to 4d was controlled at a constant value (a power ratio=1 to 1 between any two). It was shown that more of improvement was achieved on uniformity of processing in the case where a spacing (distance X2) between introduction waveguides 4b and 4c located in the central side (located in a region comparatively far from a side wall of chamber body 2) was different, in this way, from each of spacings (X1 and X3) between introducing waveguides 4a and 4d located in the outer peripheral side and between introducing waveguides 4b and 4c located in the outer peripheral side (a region comparatively close to a side wall of chamber body 2).

Then, with changes in ratio between powers introduced into respective introduction waveguides 4a to 4d in each of the arrangement at equal spacings (where X1=X2=X3) and the arrangement at different spacings (where X1 to X3 are different from one other), experiments were conducted that aim at improvement on uniformity of etching processing. Results thereof are shown in Table 1.

TABLE 1

| | | Central side power: Outer | | |
|---|---|---|---|---|
| | | peripheral side power | | |
| | | (power ratio) | | |
| | | 0.95:1 | 1:1 | 1.05:1 |
| Arrangement 1 | X1 = X2 = X3 = 280 mm | ±9.6% | ±10.5% | ±12.7% |
| Arrangement 2 | X1 = X3 = 272 mm | ±9.2% | ±7.6% | ±6.4% |
| | X2 = 320 mm | | | |

As is understood from Table 1 as well, in Arrangement 1 in a case where a power ratio is 1 to 1 (a ratio between a power of a microwave introduced into introduction waveguides 4b and 4c located in the central side and a power of a microwave introduced into introduction waveguides 4a and 4d located in the outer peripheral side is 1 to 1), uniformity of processing was ±10.5%. In Arrangement 1 in a case of a power ratio is 0.95 to 1, uniformity of processing was the best value of ±9.6%. At this time, in Arrangement 1, uniformity of processing was improved by about 9% compared with the case of a power ratio is 1 to 1.

On the other hand, in Arrangement 2, while in a case where a power ratio was 1 to 1, uniformity of processing was ±7.6%, in a case where a power ratio was 1.05 to 1, uniformity of processing was ±6.4%, which was the best. In this way, in Arrangement 2, in a case where the power ratio was 1.05 to 1, uniformity is improved by about 16% compared with a case where the power ratio was 1 to 1.

A change percent in power ratio is limited to within ±5%. This is because it is not preferable to alter a power introduced by each of introduction waveguides 4a to 4d by a great amount from the viewpoint of a construction of an apparatus such as a microwave generator of a plasma processing apparatus.

In a case where installed in a plasma processing apparatus are a plurality of microwave introducing sections introducing a microwave for generating a plasma into the chamber, the microwave introducing sections are preferably arranged at different spacings therebetween according to a construction of the apparatus in consideration of a change in a processing distribution under an influence of a side wall and the like of a chamber body (wherein a result of plasma processing is locally different due to a change in a formed plasma distribution by an influence of a side wall of a chamber body or the like). With the different spacings adopted, more of uniformity of processing can be improved than in the case of arrangement of the microwave introducing sections at equal spacings. Furthermore, with a change in ratio between introduced powers of a microwave into respective microwave introducing sections, more of uniformity of processing can be achieved.

With arrangement of microwave introducing sections at different spacings in a plasma processing apparatus, since sufficient uniformity of plasma processing can be attained, a measure is not required that a power supply is added in order to improve uniformity as was done in a conventional practice. That is, uniformity of processing can be increased at low cost. Furthermore, even in a case where ratios between powers introduced into respective microwave introducing sections do not extensively alter (even in a case where a percent of the change is restricted to a value of the order of 5%), uniformity can be sufficiently improved; therefore, adjustment in outputs of power supplies can be simpler.

That is, even though constructions of microwave introducing sections constituted of respective combinations of dielectric members 5a to 5d, slot antenna plates 6a to 6d and introduction waveguides 4a to 4d are the same as each other, plasmas generated by respective microwave introducing sections are different between conditions thereof in a region close to a side wall of chamber body 2 (in the outer peripheral region) and in a region farther from the side wall (in the central region), resulting in difference in distribution of processing such as etching. Hence, with arrangement of microwave introducing sections at different spacings so as to be adapted to a construction of a plasma processing apparatus applied, uniformity of plasma processing such as etching can be improved.

Note that the above described results are those in a case where a distance L (a gap) between the lower surfaces of dielectric members 5a to 5d and the top surface of substrate 9 to be processed is at a prescribed length. Therefore, a smaller gap leads to a smaller standard deviation of a normal distribution. On the other hand, a larger gap leads to a larger standard deviation of a normal distribution. Spacings between microwave introducing sections with uniformity of processing at a good level also alter according to a magnitude of the standard deviation. Furthermore, optimal values between spacings between microwave introducing sections (distances X1 to X3 in FIG. 7) also alter by some amount according to a plasma generation condition such as a construction of a plasma processing apparatus, a reaction gas or the like. Therefore, spacings between microwave introducing sections and arrangement thereof are determined according to a construction of a plasma processing apparatus, a processing condition or the like.

Moreover, in a plasma processing apparatus having five microwave introducing sections as shown in the second embodiment of the present invention as well, spacings between microwave introducing sections are set differently from each other, uniformity of processing can be improved in a similar way (for example, in FIG. 4, in a case where X3>X4, uniformity of processing was able to be improved more by 30% than in a case where X3=X4).

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A plasma processing apparatus comprising:
a processing chamber performing processing using a plasma; and
three or more electromagnetic wave introducing means connected to said processing chamber to introduce into said processing chamber an electromagnetic wave for driving a reaction gas supplied into said processing chamber into a plasma state, wherein
of combinations of every two adjacent ones of said three or more electromagnetic wave introducing means located in a region adjacent to said processing chamber, a distance between the two adjacent electromagnetic wave introducing means forming one of said combinations is different from a distance between the two adjacent electromagnetic wave introducing means forming another one of said combinations.

2. The plasma processing apparatus according to claim 1, wherein
said electromagnetic wave introducing means includes: dielectric members constituting part of an outer wall of said processing chamber, respectively; and waveguides connected to said dielectric members, respectively.

3. The plasma processing apparatus according to claim 1, wherein
said processing chamber includes: a wall to which said electromagnetic introducing means is connected; and a pair of side walls connected to said wall, and not only extending in a direction different from a direction along which said wall extends, but also being arranged so as to face each other, wherein
said distance between electromagnetic wave introducing means in a first combination including electromagnetic wave introducing means positioning at a point closest to one of said side walls is different from said distance between electromagnetic wave introducing means in a second combination not including said electromagnetic wave means positioning at a point closest to one of said side walls.

4. The plasma processing apparatus according to claim 1, wherein
said processing chamber includes: a wall on which said electromagnetic wave introducing means is arranged; and a pair of side walls connected to said wall, and not only extending in a direction different from a direction along which said wall extends, but also being arranged so as to face each other, wherein
each of said three or more electromagnetic wave introducing means has a major axis in a direction substantially perpendicular to a propagation direction of electromagnetic wave therein,
major axes of said three or more electromagnetic wave introducing means are aligned so as to substantially parallel to an extending direction of said side walls, and
said three or more electromagnetic wave introducing means are arranged in a parallel configuration in a direction from one of said pair of side walls to the other thereof.

5. The plasma processing apparatus according to claim 4, wherein
said distance between electromagnetic wave introducing means in a first combination including electromagnetic wave introducing means positioning at a point closest to one of said side walls is different from said distance between electromagnetic wave introducing means in a second combination not including said electromagnetic wave means positioning at a point closest to said one of said side walls.

6. The plasma processing apparatus according to claim 1, wherein
said three or more electromagnetic wave introducing means are arranged in substantially axial symmetry with respect to a location of an object to be processed placed inside of said processing chamber.

7. The plasma processing apparatus according to claim 1, wherein
said electromagnetic wave introducing means includes slot antennas disposed in propagation paths of an electromagnetic wave.

8. The plasma processing apparatus according to claim 1, wherein
an energy amount of an electromagnetic wave introduced into said processing chamber by one of said three or more electromagnetic introducing means is different from an energy amount of an electromagnetic wave introduced into said processing chamber by another of said three or more electromagnetic wave introducing means.

9. The plasma processing apparatus according to claim 1, wherein
said electromagnetic wave introducing means includes at least one of a waveguide and a dielectric member disposed adjacent to said processing chamber.

10. The plasma processing apparatus according to claim 1, wherein
a wall surface of said processing chamber includes at least one dielectric member capable of transmitting said electromagnetic wave, and
said three or more electromagnetic introducing means each includes three or more slots formed in a slot antenna placed on a surface of said one dielectric member.

11. A plasma processing method using a plasma processing apparatus including:
a processing chamber performing a processing using a plasma; and
three or more electromagnetic introducing means connected to said processing chamber, and introducing into said processing chamber an electromagnetic wave for driving a reaction gas supplied into said processing chamber into a plasma state, and in which,
of combinations of every two adjacent ones of said three or more electromagnetic wave introducing means located in a region adjacent to said processing chamber, a distance between the two adjacent electromagnetic wave introducing means forming one of said combinations is different from a distance between the two adjacent electromagnetic wave introducing means forming another one of said combinations, said method comprising the steps of:
placing an object to be processed inside of said processing chamber;
supplying a reaction gas into said processing chamber; and
introducing an electromagnetic wave into said processing chamber by electromagnetic wave introducing means to thereby drive said reaction gas into a plasma state and performing plasma processing on said object to be processed.
